(19) United States
(12) Patent Application Publication
(10) Pub. No.: US 2026/0334147 A1
(43) Pub. Date: Oct. 22, 2026

(54) SUBSTRATE CONTAINER

(71) Applicant: Shin-Etsu Polymer Co., Ltd., Chiyoda-ku, Tokyo (JP)

(72) Inventors: Osamu OGAWA, Saitama (JP); Kiminori TOMINAGA, Niigata (JP)

(21) Appl. No.: 19/117,394

(22) PCT Filed: Mar. 28, 2023
(86) PCT No.: PCT/JP2023/012698

§ 371 Date: Apr. 1, 2025

(30) Foreign Application Priority Data
Oct. 17, 2022 (JP) 2022-166424

(51) Int. Cl. H10P 72/10; F16K 24/00

(52) U.S. Cl. CPC H10P 72/1924; F16K 24/00

(57) ABSTRACT

A substrate container including a valve body in which the reliability of the valve opening and closing operation is improved. A substrate container includes: a container body that stores a substrate; a lid that closes an opening of the container body; and a valve body (40) that controls a flow of a gas to or from the container body. The valve body (40) includes: a block member (41) in which a communication passage (416 and 417) communicating an outside and an inside of the container body through a valve hole (466) is formed; and an elastically deformable plate-shaped valve member (45) that opens and closes the valve hole (466), and a valve seat (467) around the valve hole (466) and a seal surface (452a) of the valve member (45) are in contact with each other while being curved toward a downstream in a gas flow direction.

### TECHNICAL FIELD

The present invention relates to a substrate container including a valve body for controlling a flow of a gas to or from a container body.

### BACKGROUND ART

A substrate container for storing a substrate includes a container body, a lid for closing the opening of the container body, and a valve body for controlling a flow of a gas to or from the container body. The valve body has a check valve function, and includes a valve element and a metallic elastic member for opening and closing the valve element (see, for example, Patent Documents 1 and 2).

In the substrate container, a gas is supplied from the valve body and discharged through the valve body in order to store the substrate in an airtight state, and when the stored substrate is processed, a residual material adhering to the substrate may be discharged together with the supplied gas. Therefore, the metallic elastic member of the valve body may be corroded by the residual material.

Therefore, the present inventors have proposed a valve body using an elastic valve element for opening and closing a gas passage without using a metal member (see Patent Document 3). The valve body includes a valve opening and closing mechanism for closing a valve opening formed in the elastic valve element by its own elastic force and opening the valve opening by the pressure of gas exceeding the elastic force.

### CITATION LIST

### Patent Literature

Patent Document 1: Japanese Patent Application Laid-Open Publication No. 2008-066330

Patent Document 2: Japanese Patent Application Laid-Open Publication No. 2004-179449

Patent Document 3: Japanese Patent Application Laid-Open Publication No. 2020-088278

### SUMMARY OF INVENTION

### Technical Problem

However, in the valve body described in Patent Document 3, there are concerns that the valve opening may not be sufficiently closed due to thermal stress during washing or the elapsed time of the valve open state, that the edges of the valve opening may adhere to each other due to the pressure of the gas when performing the check valve function, that the check valve function may not work because the valve opening is not linearly closed, and that the valve opening may not be opened at a predetermined pressure. For example, when the valve hole is opened and closed by the elastic force of the plate-shaped valve member, if the contact surface between the valve member and the valve seat is linear in a cross-sectional view, one of the causes is the possibility that the closing force decreases toward the distal end.

Accordingly, the present invention has been made in view of the above issues, and aims to provide a substrate container including a valve body in which the reliability of the valve opening and closing operation is improved.

### Solution to Problem

(1) One aspect according to the present invention is a substrate container including: a container body that stores a substrate; a lid that closes an opening of the container body; and a valve body that controls a flow of a gas to or from the container body, wherein the valve body includes: a block member in which a communication passage communicating an outside and an inside of the container body through a valve hole is formed; and an elastically deformable plate-shaped valve member that opens and closes the valve hole, and a valve seat around the valve hole and a seal surface of the valve member are in contact with each other while being curved toward a downstream in a gas flow direction.

(2) In the above aspect (1), the valve member may include a planar seal surface extending along one direction in a state where no external force is applied, and the valve member may be in contact with the valve hole so as to close the valve hole in a state where the valve member is curved and elastically deformed toward the downstream in the gas flow direction.

(3) In the above aspect (1), the valve member may include a seal surface which is inclined or curved from a vertical direction toward an upstream in the gas flow direction in a state where no external force is applied, and the valve member may be in contact with the valve hole so as to close the valve hole in a state where the valve member is curved and elastically deformed toward the downstream in the gas flow direction.

(4) In any one of the above aspects (1) to (3), the valve member may be formed of a plate-shaped seal member and an elastic member that biases the seal member.

(5) In any one of the above aspects (1) to (4), the communication passage may include an inflow passage extending in a vertical direction toward an upstream of the valve hole, and the inflow passage may include an end wall inclined so as not to guide fluid toward the valve hole when the fluid flowing in the vertical direction collides with the end wall.

(6) In any one of the above aspects (1) to (5), the valve body may control the flow of the gas from the inside to the outside of the container body.

(7) In any one of the above aspects (1) to (5), the valve body may control the flow of the gas from the outside to the inside of the container body.

(8) In any one of the aspects (1) to (7), the valve body may include a filter that filters the gas.

(9) In any one of the above aspects (1) to (8), the communication passage may include an outflow passage extending toward a downstream of the valve hole, and the outflow passage may include an eave extending in a direction intersecting a vertical direction from the valve hole so that fluid having passed through the valve hole collides with the eave.

(10) In any one of the aspects (1) to (9), the block member may include a valve holder in which the valve hole is formed and a valve cover that clamps the valve member between the valve holder and the valve cover.

### Advantageous Effects of Invention

According to the present invention, it is possible to provide a substrate container including a valve body in which the reliability of the valve opening and closing operation is improved.

### BRIEF DESCRIPTION OF DRAWINGS

FIG. 1 is an exploded perspective view showing a substrate container according to a first embodiment of the present invention.

FIG. 2A is an exploded perspective view showing a valve body for air supply.

FIG. 2B is a top view showing a valve body for air supply.

FIG. 2C is a front view showing a valve body for air supply.

FIG. 2D is a bottom view showing a valve body for air supply.

FIG. 2E is a side view showing a valve body for air supply.

FIG. 2F is a cross-sectional view showing a valve body for air supply.

FIG. 3A is a perspective view showing a handle of a valve body.

FIG. 3B is a side view showing a handle of a valve body.

FIG. 4A is a perspective view showing a valve member of a valve body.

FIG. 4B is a perspective view showing a valve member of a valve body from a seal surface side.

FIG. 5A is a top view showing a valve holder of a valve body.

FIG. 5B is a front view showing a valve holder of a valve body.

FIG. 5C is a bottom view showing a valve holder of a valve body.

FIG. 5D is a perspective view showing a valve holder of a valve body from above a valve opening side.

FIG. 5E is a side view showing a valve holder of a valve body.

FIG. 5F is a perspective view showing a valve holder of a valve body from below a valve opening side.

FIG. 5G is a perspective view showing a valve holder of a valve body from above a rear side.

FIG. 5H is a rear view showing a valve holder of a valve body.

FIG. 5I is a perspective view showing a valve holder of a valve body from below a rear side.

FIG. 6A is a top view showing a valve cover of a valve body.

FIG. 6B is a front view showing a valve cover of a valve body.

FIG. 6C is a bottom view showing a valve cover of a valve body.

FIG. 6D is a side view showing a valve cover of a valve body.

FIG. 6E is a rear view showing a valve cover of a valve body.

FIG. 6F is a perspective view showing a valve cover of a valve body.

FIG. 7A is a cross-sectional view showing a valve body for exhaust.

FIG. 7B is a top view showing a valve body for exhaust.

FIG. 7C is a bottom view showing a valve body for exhaust.

FIG. 8A is a cross-sectional view showing a valve body for air supply according to a second embodiment.

FIG. 8B is a cross-sectional perspective view showing a valve body for air supply according to a second embodiment.

FIG. 8C is a top view showing a valve body for air supply according to a second embodiment.

FIG. 8D is a front view showing a valve body for air supply according to a second embodiment.

FIG. 8E is a bottom view showing a valve body for air supply according to a second embodiment.

FIG. 8F is a cross-sectional view showing a valve open state of a valve body for air supply according to a second embodiment.

FIG. 9A is a cross-sectional view showing a valve body for exhaust according to a second embodiment.

FIG. 9B is a cross-sectional perspective view showing a valve body for exhaust according to a second embodiment.

FIG. 9C is a top view showing a valve body for exhaust according to a second embodiment.

FIG. 9D is a front view showing a valve body for exhaust according to a second embodiment.

FIG. 9E is a bottom view showing a valve body for exhaust according to a second embodiment.

FIG. 9F is a cross-sectional view showing a valve open state of a valve body for exhaust according to a second embodiment.

FIG. 10A is a cross-sectional view showing a valve body including a valve member according to a third embodiment.

FIG. 10B is a cross-sectional perspective view showing a valve body including a valve member according to a third embodiment.

FIG. 11 is a cross-sectional view showing a valve body including an inflow passage according to a fourth embodiment.

### DESCRIPTION OF EMBODIMENTS

Embodiments of the present invention will be described below in detail with reference to the drawings. Throughout the embodiments of the present specification, the same members are denoted by the same reference numerals.

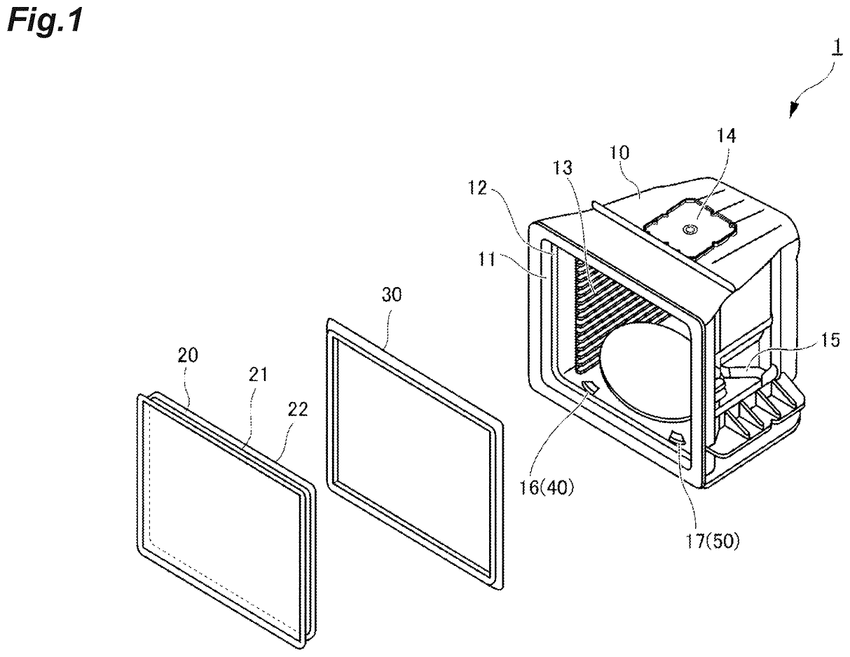

FIG. 1 is a schematic exploded perspective view showing a substrate container 1 according to a first embodiment of the present invention.

The substrate container 1 includes a container body 10 for storing a substrate, a lid 20 for closing an opening 11 of the container body 10, and an annular gasket 30 provided between the container body 10 and the lid 20.

The container body 10 is a box-like body in which the opening 11 is formed on the front. The opening 11 is bent with a step so as to expand outward, and the surface of the step is formed at the inner peripheral edge of the front of the opening 11 as a seal surface 12 with which the gasket 30 is in contact. The container body 10 is preferably a front-open type because it is easy to insert a substrate having a diameter of 300 mm or 450 mm.

Supports 13 are disposed on both the left and right sides inside the container body 10. The support 13 has a function of mounting and positioning a substrate. In the support 13, a plurality of grooves is formed in the height direction to constitute so-called groove teeth. The substrate is mounted on two groove teeth on the left and right at the same height. The material of the support 13 may be the same as that of the container body 10, but different materials may be used in order to enhance washability and slidability.

A rear retainer (not shown) is disposed at the rear (inner side) inside the container body 10. When the lid 20 is closed, the rear retainer pairs with a front retainer, which will be described later, to hold the substrate. Without providing a rear retainer as in the present embodiment, the supports 13 may include a substrate holder with a shape such as a “V”-shape or linear shape on the inner side of the groove teeth, so that the substrate is held by the front retainer and the substrate holder. The supports 13 and the rear retainer may be provided in the container body 10 by insert molding or fitting.

The substrate is stored in the container body 10 while being supported by the supports 13. An example of the substrate is a silicon wafer, but it is not particularly limited to this, and the substrate may be, for example, a quartz wafer, a gallium arsenide wafer, or the like.

A robotic flange 14 is detachably provided at the center of the ceiling of the container body 10. The robotic flange 14 is held by a transfer robot in a factory, and the substrate container 1, which airtightly stores the substrate in a clean state, is conveyed to a processing device for each step of processing the substrate.

Manual handles 15, which can be held by an operator, are detachably mounted on the center of the outer surfaces on both sides of the container body 10.

An air supply portion 16 and an exhaust portion 17 are provided on the inner bottom surface of the container body 10, and valve bodies 40 and 50, which will be described later, are attached to the outer bottom surface of the container body 10. An inert gas such as nitrogen gas or dry air is supplied from the air supply portion 16 to the inside of the substrate container 1, which is closed by the lid 20, and is discharged from the exhaust portion 17 as necessary. This process allows for the replacement of the gas inside the substrate container 1, maintaining a low-humidity airtight state, and blowing off impurities on the substrate, thereby maintaining the cleanliness of the inside of the substrate container 1. In addition to supplying the gas from the air supply portion 16, the exhaust portion 17 may be connected to a negative pressure (vacuum) generator to forcibly discharge the gas from the exhaust portion 17.

Further, by detecting the gas exhausted from the exhaust portion 17, it is possible to confirm whether or not the inside of the substrate container 1 has been replaced with the introduced gas. Although it is preferable that the air supply portion 16 and the exhaust portion 17 are positioned away from the position where the substrate is projected onto the bottom surface, the number and positions of the air supply portion 16 and the exhaust portion 17 are not limited to those shown in the drawing, and may be positioned at four corners of the bottom surface of the container body 10. The air supply portion 16 and the exhaust portion 17 may be attached to the lid 20.

On the other hand, the lid 20 has a substantially rectangular shape and is attached to the front of the opening 11 of the container body 10. The lid 20 includes a locking mechanism (not shown), and is locked by fitting a locking piece into a locking hole (not shown) formed in the container body 10.

An elastic front retainer (not shown) for horizontally holding the front peripheral edge of the substrate is detachably mounted to the central part of the lid 20 by fitting or the like, or is integrally formed by insert molding or the like. Since the front retainer, like the groove teeth and the substrate holder of the support 13, is a part where the wafer comes into direct contact, a material having good washability and slidability is used for the front retainer.

A mounting groove 21 for mounting the gasket 30 is formed in the lid 20. For example, on the surface of the lid 20 facing the container body 10, a protrusion 22 smaller than the step portion of the opening 11 may be formed in an annular shape, so that the mounting groove 21 having a substantially U-shaped cross section may be formed in an annular shape. When the lid 20 is attached to the container body 10, the protrusion 22 is inserted deeper than the step portion of the opening 11.

Examples of the material of the container body 10 and the lid 20 include thermoplastic resins such as polycarbonate, cycloolefin polymer, polyether ether ketone, and liquid crystal polymer. The thermoplastic resin may suitably contain a conductive agent including a conductive carbon, a conductive fiber, a metal fiber, a conductive polymer or the like, various antistatic agents, an ultraviolet absorber or the like.

The gasket 30 has an annular shape corresponding to the front shape of the lid 20 (and the shape of the opening 11 of the container body 10), and has a rectangular frame shape in the present embodiment. The annular gasket 30 may have an annular (ring) shape before being attached to the lid 20.

The gasket 30 is positioned between the seal surface 12 of the container body 10 and the lid 20. When the lid 20 is attached to the container body 10, the gasket 30 adheres closely to both the seal surface 12 and the lid 20 to ensure the airtightness of the substrate container 1. This reduces the intrusion of dust, moisture, and the like into the substrate container 1 from the outside and reduces the leakage of gas from the inside to the outside.

The gasket 30 may be formed of an elastic material such as a thermoplastic elastomer made of a polyester elastomer, a polyolefin elastomer, a fluorine elastomer, or a urethane elastomer, a fluororubber, an ethylene propylene rubber, or a silicone rubber. Various additives may be added to these materials in order to add other functions.

Next, a valve body 40 for air supply will be described.

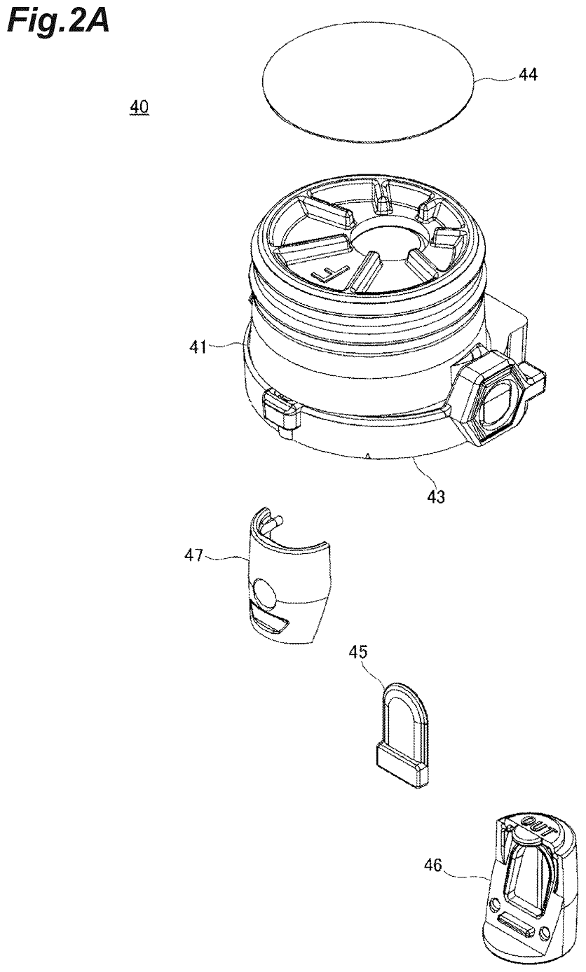

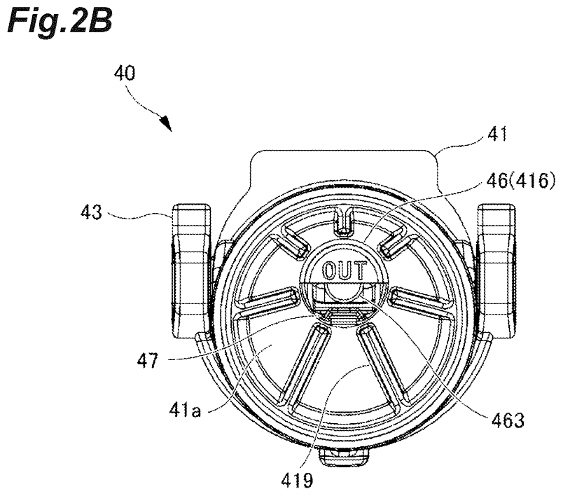

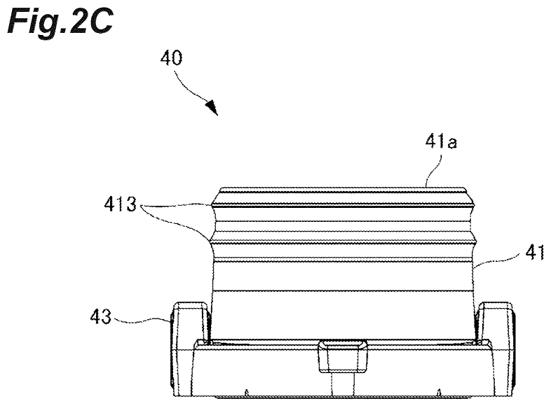

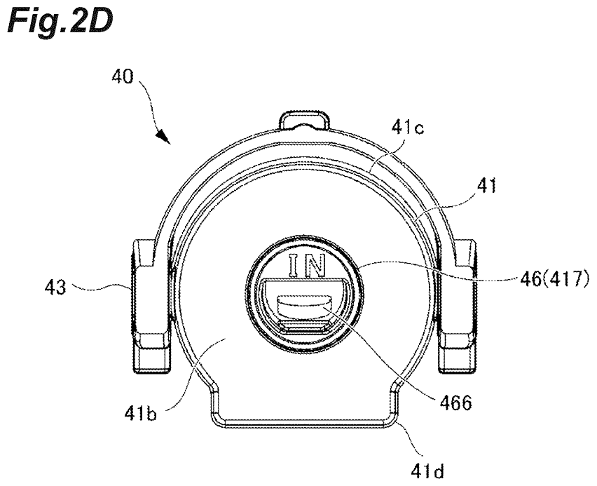

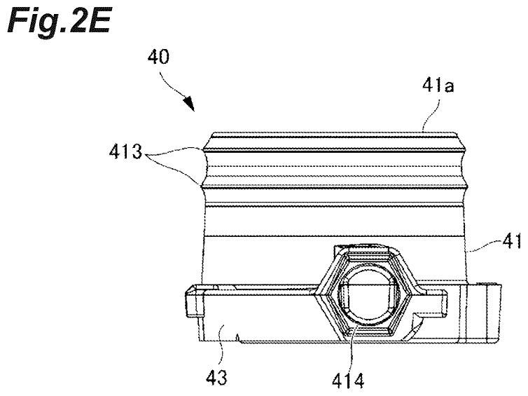

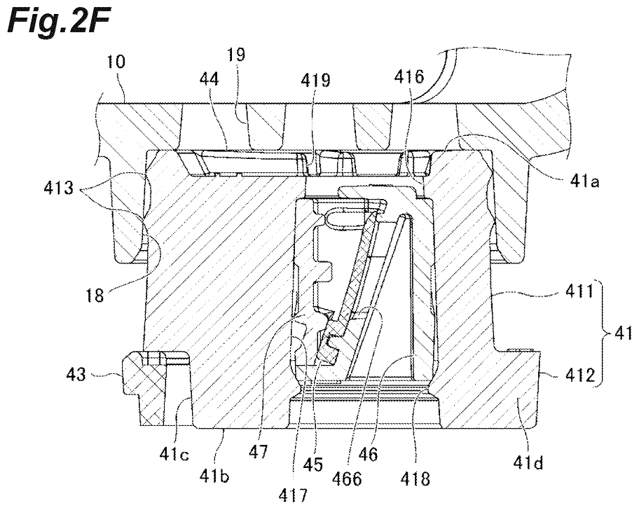

FIGS. 2A to 2F show the valve body 40 for air supply, where FIG. 2A is an exploded perspective view, FIG. 2B is a top view, FIG. 2C is a front view, FIG. 2D is a bottom view, FIG. 2E is a side view, and FIG. 2F is a cross-sectional view. In FIG. 2F, the bottom surface of the container body 10 is also drawn.

The valve body 40 controls the flow of gas to the container body 10, and communicates with the air supply portion 16 through a gas flow passage (not shown) when attached to the container body 10. As shown in FIG. 2F, the valve body 40 includes a block member 41 fitted into a through hole 18 formed by a rib of the bottom surface of the container body 10 (or a bottom plate attached to the bottom surface of the container body 10). A plurality of ventilation ribs 19 is formed on the base end side of the through hole 18 so as to ensure the flow of the gas to the container body 10.

The block member 41 includes a cylindrical first cylindrical portion 411 and a second cylindrical portion 412 having a central axis displaced from the central axis of the first cylindrical portion 411 (see FIG. 2F).

One or more annular ribs 413 are formed on the outer peripheral surface of the first cylindrical portion 411. The annular rib 413 is fitted into the through hole 18 of the container body 10 to fix the valve body 40 to the substrate container 1, and also has a function of ensuring airtightness between the block member 41 and the through hole 18.

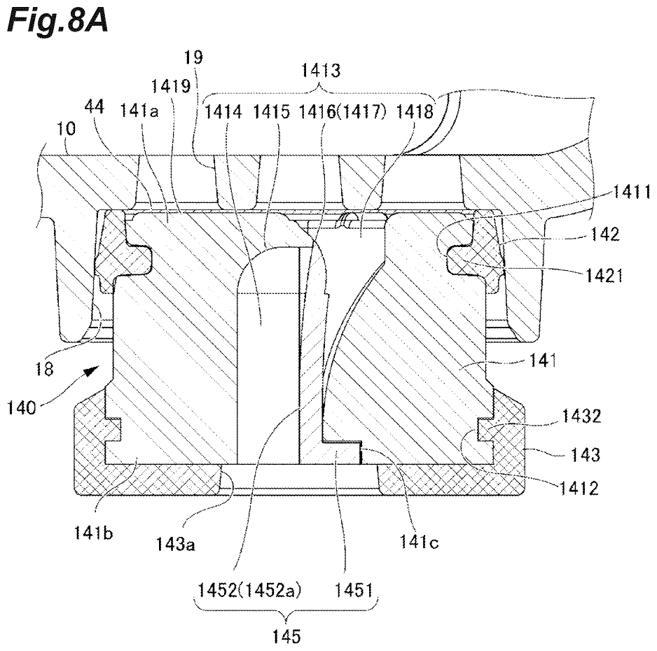

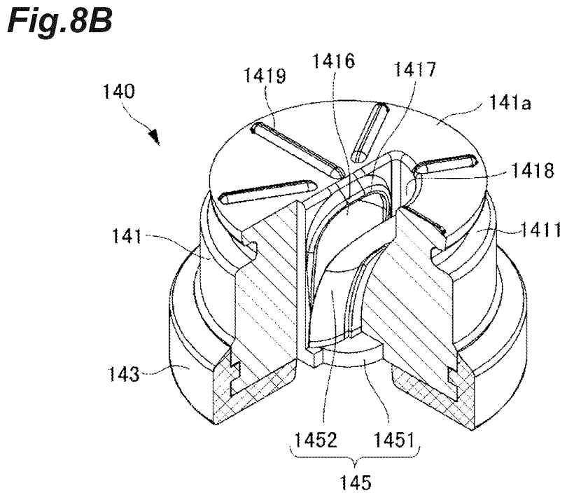

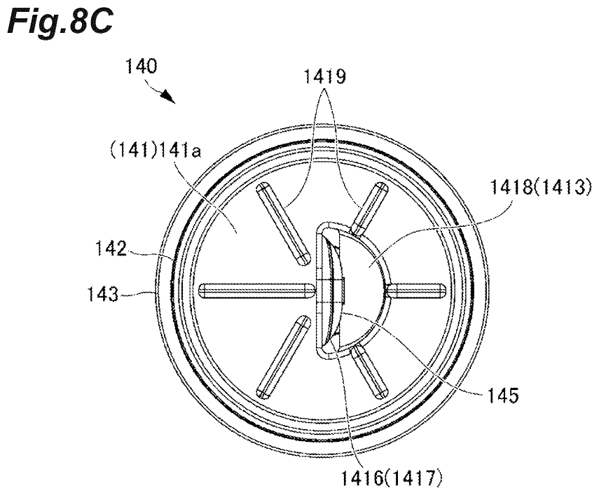

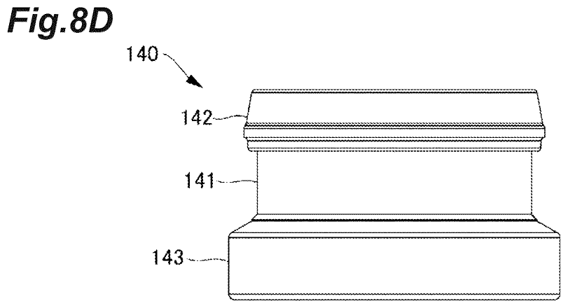

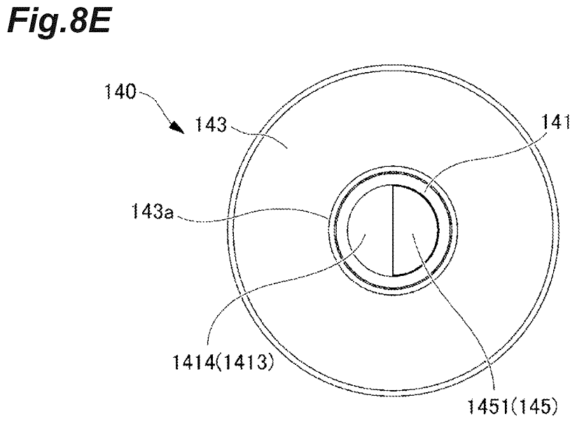

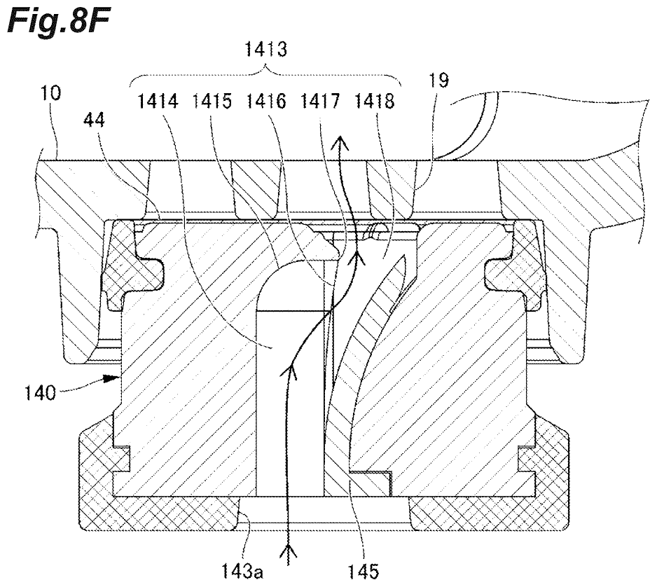

Instead of the annular rib 413, a ring groove or the like may be formed on the outer peripheral surface, and a seal ring made of a material such as fluororubber, natural rubber, urethane rubber, ethylene propylene rubber, or the like may be fitted therein (see FIG. 8A of the second embodiment described later).

Partition ribs 419 extending radially from a vent hole 416 is erected on the upper surface 41a of the first cylindrical portion 411 facing the container body 10 (see FIG. 2B). The vent hole 416 is formed such that the central axis thereof is displaced from the central axis of the first cylindrical portion 411.

Further, a storage hole 417 communicating with the vent hole 416 is also formed in the first cylindrical portion 411 (see FIG. 2F). The storage hole 417 has an inner diameter larger than that of the vent hole 416.

Further, in the storage hole 417, an annular locking rib 418 is formed near the opening edge of the second cylindrical portion 412. The storage hole 417 is designed to house a valve assembly, which will be described later, between the vent hole 416 and the locking rib 418. In the valve body 40, the vent hole 416 and the storage hole 417 function as an outflow passage and an inflow passage forming a part of the communication passage, respectively.

On the other hand, a pair of support shafts 414 protrude along a direction substantially perpendicular to the central axis of the second cylindrical portion 412 on the outer peripheral surface of the second cylindrical portion 412. The support shafts 414 have a cylindrical shape with a chamfered upper portion (see FIG. 2E). Since the second cylindrical portion 412 is displaced with respect to the first cylindrical portion 411, a step portion 41c is formed on one side and a protruding portion 41d is formed on the opposite side. The protruding portion 41d is formed in a rectangular shape.

The block member 41 having such a shape is made of, for example, a thermoplastic resin such as polycarbonate, polyether imide, polyether ether ketone, or liquid crystal polymer.

A handle 43 is rotatably attached to the pair of support shafts 414 of the block member 41.

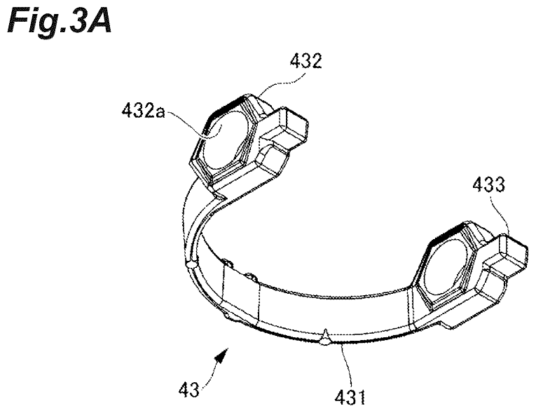

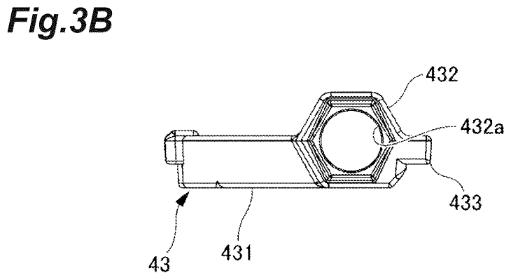

FIGS. 3A and 3B show the handle 43 of the valve body 40, where FIG. 3A is a perspective view and FIG. 3B is a side view.

The handle 43 is formed in a substantially U-shape and includes an arc-shaped body portion 431 and bearings 432 provided at both ends of the body portion 431. Shaft holes 432a, into which the support shafts 414 of the block member 41 are inserted, are formed in the bearings 432 (see FIG. 3A).

Further, a protruding piece 433 is formed on the side of the bearing 432 opposite to the side connected to the body portion 431. The protruding piece 433 is used when the valve body 40 is attached to the container body 10, and when the handle 43 is rotated to the housed state, the valve body 40 is fitted into the through hole 18 by the principle of a lever using the attachment portion of the container body 10 as a fulcrum (see Patent Document 1 for details).

The handle 43 is made of, for example, a thermoplastic resin such as polycarbonate, polyether imide, polyether ether ketone, or liquid crystal polymer.

Here, one or more filters 44 are disposed on the upper surface 41a of the block member 41 (above the partition ribs 419) so as to be clamped between the upper surface 41a and the ventilation rib 19 of the container body 10 (see FIG. 2F). The filter 44 may be attached to the container body 10 or the upper surface 41a of the block member 41 by, for example, adhesion or welding.

The filter 44 filters a gas to be supplied or a discharged gas, and is selected from a porous membrane made of tetrafluoroethylene, polyester fiber, fluorine resin, etc., a molecular filter made of glass fiber, etc., a chemical filter in which a chemical adsorbent is carried on a filter medium such as activated carbon fiber, etc.

When using multiple filters 44, it is acceptable to use filters of the same type; however, it is preferable to combine filters with different properties. This combination can prevent not only particles but also contamination by organic substances. For example, a hydrophobic or hydrophilic material may be used for one of the filters 44 to suppress the permeation of a liquid. This is because such a material functions to suppress the retention of a liquid such as water or a washing liquid or suppress the passage of a liquid when the container body 10 is washed.

A valve assembly including a valve member 45, a valve holder 46, and a valve cover 47 is housed in the storage hole 417 of the block member 41.

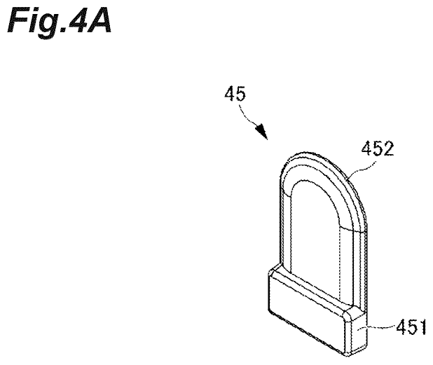

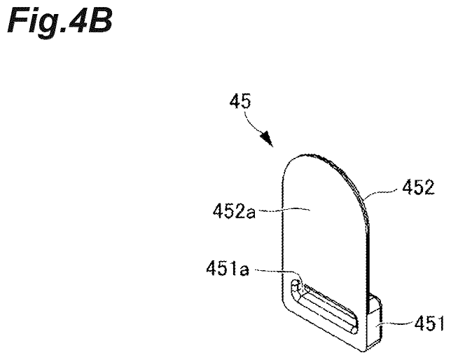

FIGS. 4A and 4B show the valve member 45 of the valve body 40, where FIG. 4A is a perspective view and FIG. 4B is a perspective view from the seal surface 452a.

The valve member 45 is elastically deformable, designed to sit on a valve seat 467 of the valve holder 46, which will be described later, and to open and close a valve hole 466. The valve member 45 includes a thick base portion 451 and a thin seal portion 452 (see FIG. 3A).

On the seal surface 452a side of the base portion 451, a fitting recess 451a is formed. The fitting recess 451a is designed to be clamped and fixed between the valve holder 46 and the valve cover 47 by being mounted onto a fitting protrusion 464 of the valve holder 46, which will be described later (see FIG. 3B). The fitting recess 451a, as long as it can fit and lock with the fitting protrusion, is not limited to the above-mentioned elongated groove shape, and may be one or more cylindrical or prismatic recesses, or any other shape.

On the other hand, the seal portion 452 is formed in a tongue piece shape (lead shape) extending from the base portion 451. The seal portion 452 may have a uniform thickness throughout, but in the present embodiment, it has a constant thickness up to a certain point and gradually becomes thinner from the certain point toward the outer edge.

One surface of the seal portion 452 is a seal surface 452a. The seal surface 452a is formed to align with, for example, a plane extending in the vertical direction in a state where no external force is applied (standalone state). The seal surface 452a may be inclined or curved toward the opposite side of the seal surface 452a in a state where no external force is applied. The shape of the seal portion 452 is not limited to an oval shape, and may be a rectangular shape (strip shape) depending on the shape of the valve hole 466.

Such a valve member 45 may be formed using various types of rubber, thermoplastic resins, or the like depending on the desired magnitude of the elastic (restoring) force. Examples of these rubbers and resins include rubber such as fluororubber and ethylene propylene rubber, thermoplastic elastomers such as polyester elastomers, polyolefin elastomers, fluorine elastomers, and urethane elastomers, and resins such as polyether ether ketone, polybutylene terephthalate, and polycarbonate. The material may be selected based on performance conditions such as prioritizing the sealing (adhesion) property with the valve seat 467, prioritizing anti-stick property to the valve seat 467, or prioritizing washability and dryability.

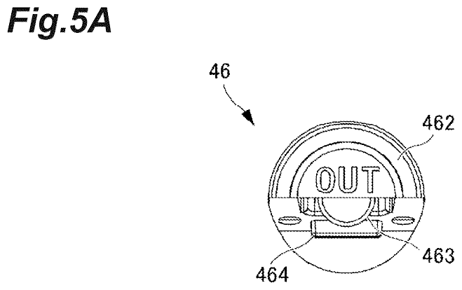

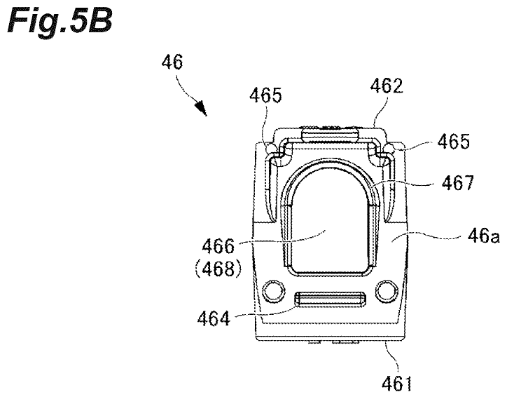

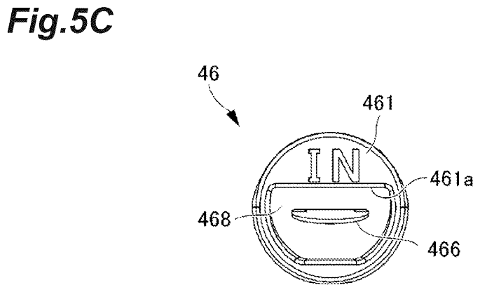

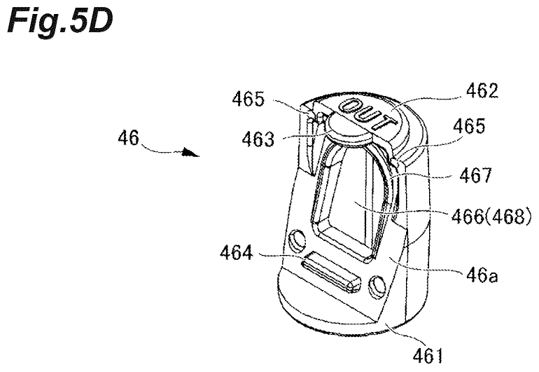

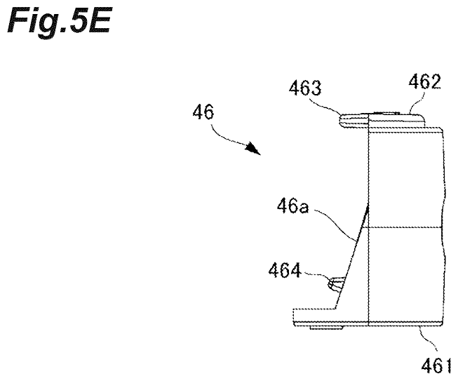

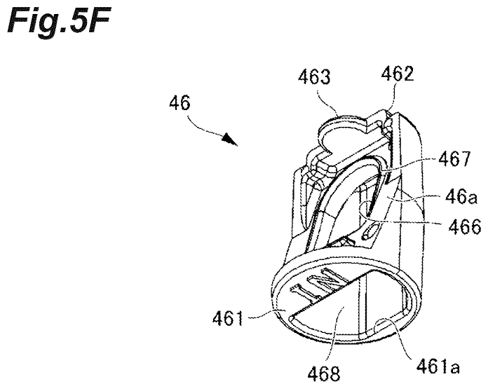

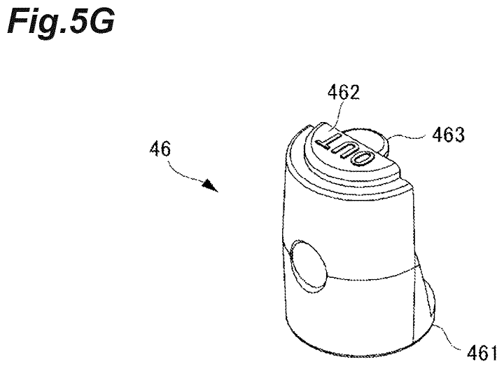

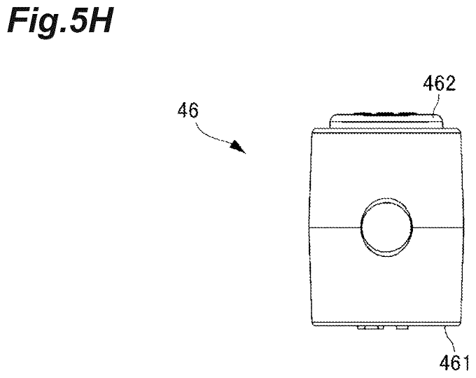

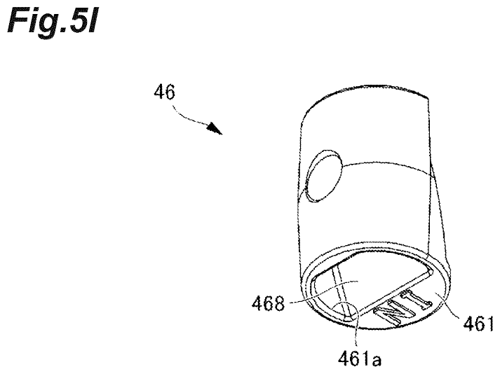

FIGS. 5A to 5I show the valve holder 46 of the valve body 40, where FIG. 5A is a top view, FIG. 5B is a front view, FIG. 5C is a bottom view, FIG. 5D is a perspective view from above the valve opening side, FIG. 5E is a side view, FIG. 5F is a perspective view from below the valve opening side, FIG. 5G is a perspective view from above the rear side, FIG. 5H is a rear view, and FIG. 5I is a perspective view from below the rear side.

Next, the valve holder 46 is formed in a substantially semi-cylindrical shape, cut by a valve seat forming surface 46a that intersects the central axis, so that when combined with the valve cover 47 and the valve member 45, which will be described later, the valve holder 46 forms a substantially cylindrical or barrel shape (see FIG. 5F). That is, the cylindrical surface which is the outer surface of the valve holder 46, the end face 461 on one side, the end face 462 on the other side, and the valve seat forming surface 46a form the cavity 468 through which the gas flows.

The valve holder 46 has a diameter such that the outer peripheral surface (outer diameter) of the valve holder 46 is equal to or slightly larger than the inner peripheral surface (inner diameter) of the storage hole 417 of the block member 41. The valve holder 46 is formed to have a length that is equal to or slightly larger than the height of the storage hole 417 (the height from the vent hole 416 to the locking rib 418). A ring-shaped rib or the like may be added to the outer peripheral surface of the valve holder 46 to increase the fitting frictional force.

The end face 461 on one side is substantially circular, and a semicircular (more precisely, larger than a semicircle) inflow port 461a that leads to the cavity 468 is formed in the end face 461 (see FIG. 5C). Further, the end face 462 on the other end side is semicircular, and a small-diameter semicircular eave 463 is provided to protrude in the diametric direction from the end face 462 (see FIG. 5A). The eave 463 extends in the same plane as the end face 462, i.e., in a direction orthogonal to the vertical direction. The eave 463 is not limited to extending in the direction orthogonal to the vertical direction, for example, the eave 463 may extend in a direction intersecting the vertical direction, such as being inclined or curved toward the valve hole 466.

As will be described later, since the valve holder 46 is a common component in the valve body 40 for air supply and a valve body 50 for exhaust, letters, numbers, symbols, etc. of “IN” and “OUT” may be added to the end face 461 and the end face 462 by engraving, printing, coloring, or other methods to distinguish the application (gas flow direction).

The tongue-shaped valve hole 466 connected to the cavity 468 is opened in the valve seat forming surface 46a (see FIG. 5B). The valve hole 466 may have an opening area of, for example, 30 mm² or more and 100 mm² or less.

The valve seat 467 is formed at the opening edge of the valve hole 466. The valve seat 467 is not located on a plane obtained by translating the valve seat forming surface 46a, but is located on a curved surface such that the end face 462 protrudes from the end face 461 in a side view of the valve seat forming surface 46a. As a result, the seal region where the valve member 45 and the valve seat 467 come into contact also becomes curved (see also FIGS. 8A and 8B of the second embodiment).

The curve forming the curved surface may match, for example, a part of a parabola such as a quadratic function, a cubic function, or a quartic function, or a part of an arc or a catenary curve. The displacement amount of the portion corresponding to the distal end of the valve member 45 may be, for example, equal to or less than the thickness of the valve member 45, but is not limited thereto.

Near the end face 461 on the valve seat forming surface 46a, the rectangular fitting protrusion 464 for locking the valve member 45, which will be described later, is formed protruding. Further, near the end face 462 on the valve seat forming surface 46a, two locking recesses 465 are formed as locking means for locking the valve cover 47 described later.

The valve holder 46 is made of a material which is difficult to adhere to the material forming the valve member 45, for example, cycloolefin polymer, polyether ether ketone, polyolefin methacrylate, polypropylene, polybutylene terephthalate, or polycarbonate.

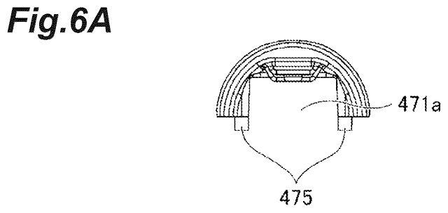

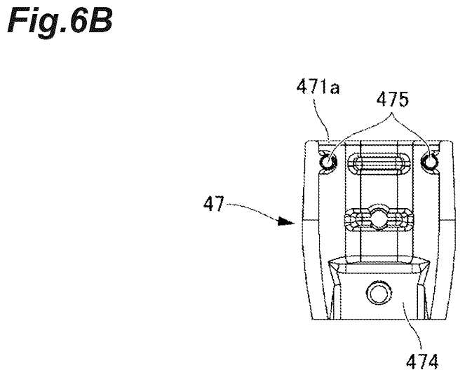

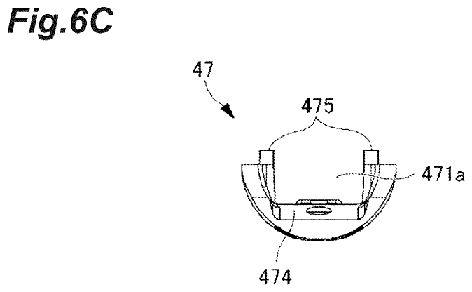

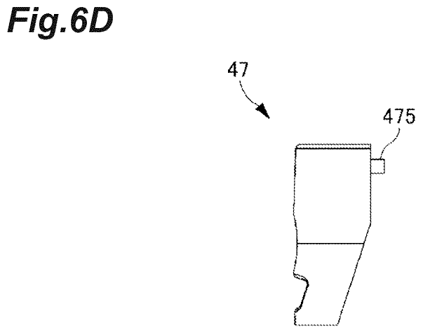

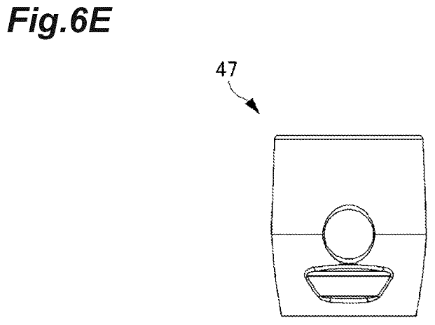

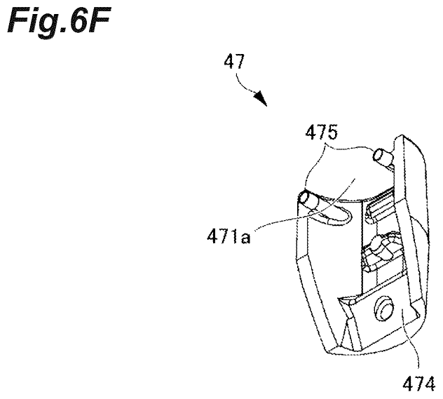

FIGS. 6A to 6F show the valve cover 47 of the valve body 40, where FIG. 6A is a top view, FIG. 6B is a front view, FIG. 6C is a bottom view, FIG. 6D is a side view, FIG. 6E is a rear view, and FIG. 6F is a perspective view.

The valve cover 47 has a substantially semi-cylindrical shape, and both end face portions of the semicircular shape are open, and one end is an outflow port 471a through which gas can flow (see FIG. 6F). The end portion of the peripheral wall of the valve holder 46 is inclined or bent to conform to the shape of the valve seat forming surface 46a.

A locking protrusion 475 as a locking means is provided on the upper inner surface of the valve cover 47, positioned at one end of the valve holder 46. By fitting the locking protrusion 475 into a locking recess 465 of the valve holder 46, the valve holder 46 and the valve cover 47 can be locked and integrated with the valve member 45 interposed between them.

Further, a valve presser 474 protrudes from the lower inner surface of the valve cover 47, positioned at the other end of the valve holder 46. A reinforcing rib or the like is also formed on the inner surface of the valve cover 47, and excessive deformation of the valve member 45 can be prevented by having the valve member 45 come into contact with the reinforcing rib.

Similar to the valve holder 46, the valve cover 47 is made of, for example, a thermoplastic resin such as polycarbonate, polyether imide, polyether ether ketone or liquid crystal polymer.

Finally, the operation of the valve body 40 in controlling the flow of gas will be described.

In the valve body 40, when no positive pressure is applied to the inflow port (inflow passage) 461a (or the cavity 468) of the storage hole 417, the valve member 45 comes into close contact with the valve seat 467 to block the flow of the gas in both directions. Then, for example, when a positive pressure of a predetermined value or more is applied to the inflow port 461a, the valve member 45 deforms toward the outflow port 471a (outflow passage) (or the vent hole 416) according to the magnitude of the positive pressure, thereby opening the valve hole 466. In this way, the gas supplied from the outside of the container body 10 passes through the valve hole 466 and is supplied to the inside of the container body 10.

When a negative pressure of the predetermined value or more is applied to the outflow passage, the valve body 140 performs the same valve opening operation as when a positive pressure of the predetermined value or more is applied to the inflow passage, because this is relatively the same as when the positive pressure is applied to the inflow passage.

On the contrary, when the positive pressure is applied to the outflow passage, the valve member 45 is further pressed against the valve seat 467 while remaining in close contact with the valve seat 467, so that the gas does not pass through the valve hole 466, and the blocking of the flow is maintained.

In the valve body 40, the predetermined value of the pressure at which the gas can flow can be adjusted by changing the material, hardness, shape, dimension, and thickness of the valve member 45 and the opening area (width and length) of the valve hole 466.

Next, the valve body 50 for exhaust will be described. Since the valve body 50 for exhaust is basically constituted by the same components as the valve body 40 for air supply, except for the insertion direction of the valve assembly housed in the storage hole 417 of the block member 41 of the valve body 40, the description of individual components will be omitted as appropriate.

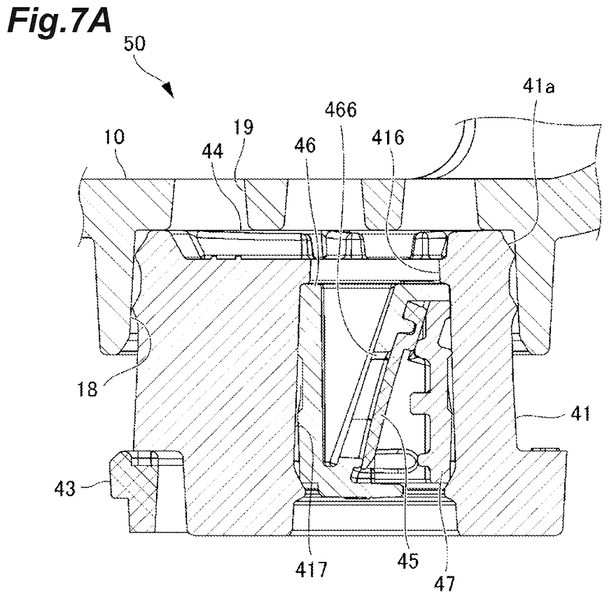

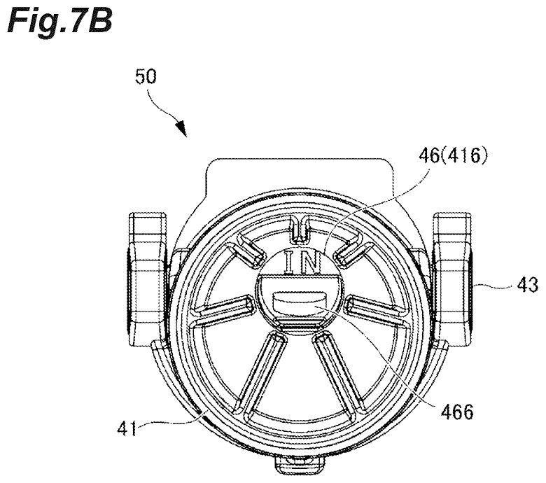

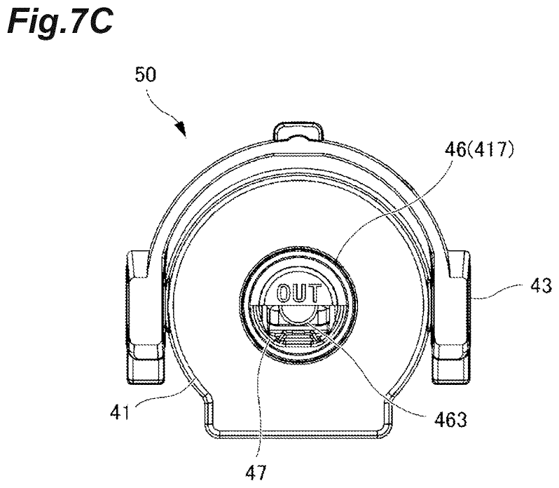

FIGS. 7A to 7C show the valve body 50 for exhaust, where FIG. 7A is a cross-sectional view, FIG. 7B is a top view, and FIG. 7C is a bottom view. A part of the container body 10 to which the valve body 50 is attached is also shown in FIG. 7A.

As shown in FIG. 7A, the valve body 50 controls the flow of gas from the container body 10, and communicates with the exhaust portion 17 through a gas flow passage (not shown) when attached to the container body 10. Contrary to the valve body 40, the valve body 50 is used for the exhaust portion 17, which enables the exhaust of gas from the container body 10 to the outside but disables the supply of gas to the inside of the container body 10.

The valve body 50 is obtained by inserting the valve assembly (the valve member 45, the valve holder 46, and the valve cover 47) of the valve body 40 in such a manner that the valve assembly is basically inverted upside down. That is, the inflow port 461a of the valve holder 46 is positioned upward (toward the container body 10), and the outflow port 471a of the valve cover 47 is positioned downward (toward the outside) (see FIG. 7A).

The operation of the valve body 50 for exhaust in controlling the flow of the gas is basically the reverse of that of the valve body 40 for air supply, therefore, a description thereof will be omitted. The pressure at which the valve body 50 is opened may be different from the pressure at which the valve body 40 is opened.

Next, valve bodies 140 and 150 according to the second embodiment will be described.

The valve body 40 of the first embodiment is obtained by inserting the valve member 45, the valve holder 46, and the valve cover 47, which constitute the reed valve, as one valve assembly into the block member 41, and then fitting and mounting the block member 41 in the through hole 18. The valve body 140 of the second embodiment is different in that a block member 141 directly including the valve member 45 is fitted and mounted in the through hole 18.

FIGS. 8A to 8F show the valve body 140 for air supply, where FIG. 8A is a cross-sectional view, FIG. 8B is a cross-sectional perspective view, FIG. 8C is a top view, FIG. 8D is a front view, FIG. 8E is a bottom view, and FIG. 8F is a cross-sectional view showing a valve open state. A part of the container body 10 to which the valve body 140 is attached is also shown in FIG. 8A.

The valve body 140 controls the flow of gas from the outside to the inside of the container body 10, and communicates with the air supply portion 16 through a gas flow passage (not shown) when attached to the container body 10.

As shown in FIG. 8A, the valve body 140 is fitted into the through hole 18 formed by a rib of the bottom surface of the container body 10 (or a bottom plate attached to the bottom surface of the container body 10). A plurality of ventilation ribs 19 is formed on the base end side of the through hole 18 so as to ensure the flow of the gas to the container body 10.

The block member 141 has a cylindrical shape in which a first ring groove 1411 and a second ring groove 1412 are formed on the outer peripheral surface. The block member 141 includes a circular first surface (hereinafter referred to as the “upper surface”) 141a facing the container body 10, and a circular second surface (hereinafter referred to as the “lower surface”) 141b facing away from the container body 10.

On the upper surface 141a of the block member 141, partition ribs 1419 extending radially from the vicinity of the central axis is erected (see FIG. 8C).

A communication passage 1413 is formed around the central axis of the block member 141. The communication passage 1413 includes an inflow passage 1414 opened to the lower surface 41b, a valve hole 1416, and an outflow passage 1418 opened to the upper surface 141a.

The inflow passage 1414 is a semi-cylindrical cavity, with the flat side forming the valve hole 1416. The inflow passage 1414 has an end portion on the upper surface 141a side that is formed as an end wall 1415 having a substantially quarter-spherical shape, which guides the inflow gas to the valve hole 1416. The valve hole 1416 is not precisely located on a plane passing through the central axis, but is located on a curved surface in which the upper surface 141a side is curved toward the outflow passage 1418, as will be described later.

On the other hand, the outflow passage 1418 has a semicircular outflow port facing the upper surface 41a (see FIG. 8C) and a wall surface curved so as to narrow toward the valve hole 1416 and the lower surface 141b. The cross-sectional areas of the inflow passage 1414 and the outflow passage 1418 are appropriately designed in accordance with the flow rate and the pressure of the gas, or in accordance with the maximum opening amount of the valve hole 1416 and the Cv value.

A semicircular step portion 141c is formed on the lower surface 141b of the block member 141, and is located on the opposite side of the inflow passage 1414 across the central axis.

The block member 141 is made of, for example, a thermoplastic resin such as polycarbonate, polyether imide, polyether ether ketone, or liquid crystal polymer.

Subsequently, an annular first seal ring 142 is mounted in the first ring groove 1411 of the block member 141. The first seal ring 142 includes an annular protrusion 1421 which is fitted into the first ring groove 1411 on the inner periphery thereof.

The first seal ring 142 ensures airtightness between the block member 141 and the through hole 18 when the block member 141 is inserted into the through hole 18 of the container body 10, and also has a function of fixing the block member 141 by being fitted into the through hole 18 (see FIG. 8A).

On the other hand, a bottomed annular second seal ring 143 is mounted in the second ring groove 1412 of the block member 141. The second seal ring 143 includes an annular protrusion 1432 which is fitted into the second ring groove 1412 on the inner periphery thereof. A circular through hole 143a is formed in the center of the bottom plate of the second seal ring 143 (see FIG. 8A).

The second seal ring 143 ensures airtightness between the valve body 140 and the nozzle of the load port when the substrate container 1 is placed on the load port.

A U-shaped handle may be foldably attached to the second seal ring 143 to facilitate attachment and detachment of the valve body 140.

The first seal ring 142 and the second seal ring 143 may be made of a material such as fluororubber, natural rubber, urethane rubber, or ethylene propylene rubber. For example, letters, numbers, symbols, or colors may be added to the first seal ring 142 and the second seal ring 143 (or the block member 141 itself) by engraving, printing, coloring, or other methods to distinguish the air supply valve body 140 and the exhaust valve body 150, which will be described later, from each other externally.

Here, one or more filters 44 are disposed on the upper surface 41a of the block member 141 (above the partition ribs 1419) so as to be clamped between the upper surface 41a and the ventilation rib 19 of the container body 10 (see FIG. 8A). The filter 44 may be attached to the container body 10 or the upper surface 141a of the block member 141 by, for example, adhesion or welding.

The filter 44 filters a gas to be supplied or a discharged gas, and is selected from a porous membrane made of tetrafluoroethylene, polyester fiber, fluorine resin, etc., a molecular filter made of glass fiber, etc., a chemical filter in which a chemical adsorbent is carried on a filter medium such as activated carbon fiber, etc.

When using multiple filters 44, it is acceptable to use filters of the same type; however, it is preferable to combine filters with different properties. This combination can prevent not only particles but also contamination by organic substances. For example, a hydrophobic or hydrophilic material may be used for one of the filters 44 to suppress the permeation of a liquid. This is because such a material functions to suppress the retention of a liquid such as water or a washing liquid or suppress the passage of a liquid when the container body 10 is washed.

Next, a valve member 145 will be described together with the valve hole 1416 and a valve seat 1417.

The valve member 145 is elastically deformable to open and close the valve hole 1416, and includes a semicircular plate-shaped base portion 451 and a lead-shaped (or tongue-shaped) seal portion 1452 (see FIG. 8A). The base portion 1451 and the seal portion 1452 are connected to each other in an L-shape having a right angle or a substantially right angle in a cross-sectional view taken in a direction orthogonal to the flow direction of the gas passing through the valve hole 1416.

The base portion 1451 is formed to have a uniform thickness equal to or slightly thicker than the height of the step portion 141c of the block member 141, and is designed to be clamped and fixed between the block member 141 and the second seal ring 143 by being mounted to the step portion 141c.

On the other hand, the seal portion 1452 may have a uniform thickness throughout, but in the present embodiment, it has a constant thickness up to a certain point and gradually becomes thinner from the certain point toward the outer edge.

The seal portion 1452 includes a seal surface 1452a on the side opposite to the extending direction of the base portion 1451. The seal surface 1452a is formed to align with, for example, a plane extending in the vertical direction along the central axis of the block member 141 in a state where no external force is applied (standalone state). The seal surface 1452a may be inclined or curved from the vertical direction toward the upstream (inflow passage 1414) of the gas flow direction so as to form an obtuse angle with respect to the base portion 1451 in a state where no external force is applied.

Such a valve member 145 may be formed using various types of rubber, thermoplastic resins, or the like depending on the desired magnitude of the elastic (restoring) force. Examples of these rubbers and resins include rubber such as fluororubber and ethylene propylene rubber, thermoplastic elastomers such as polyester elastomers, polyolefin elastomers, fluorine elastomers, and urethane elastomers, and resins such as polyether ether ketone, polybutylene terephthalate, and polycarbonate. The material may be selected based on performance conditions such as prioritizing the sealing (adhesion) property with the valve seat 1417, prioritizing anti-stick property to the valve seat 1417, or prioritizing washability and dryability.

Referring back to FIG. 8A, the valve hole 1416 and the valve seat 1417 will be described. The valve hole 1416, which is opened and closed by the valve member 145, has a semicircular shape on the upper surface 141a of the block member 141, and the periphery of the valve hole 1416 is formed as the valve seat 1417.

The valve hole 1416 and the valve seat 1417 are not located on a plane (vertical plane) passing through the central axis of the block member 141, but are located on a curved line in which the upper surface 41a side is curved toward the outflow passage 1418 in a cross-sectional view from a direction orthogonal to the central axis of the block member 141.

The curve forming the curved surface may match, for example, a part of a parabola such as a quadratic function, a cubic function, or a quartic function, or a part of an arc or a catenary curve. The displacement amount of the distal end of the valve member 145 toward the outflow passage 1418 may be, for example, equal to or less than the thickness of the seal portion 452, but is not limited thereto.

In the seal surface where the valve member 145 and the valve seat 1417 are in contact with each other, the upper surface 141a side is curved toward the outflow passage 1418 in a cross-sectional view in a direction orthogonal to the central axis of the block member 141. In this state, the valve member 145 is in contact with the valve seat 1417 so as to close the valve hole 1416 in a state in which the valve member 145 is elastically deformed so as to oscillate with the base portion 1451 as a fulcrum axis.

Next, the operation of the valve body 140 in controlling the flow of gas will be described.

In the valve body 140, when no positive pressure is applied to the inflow passage 1414, the valve member 145 comes into close contact with the valve seat 1417 to block the flow of the gas in both directions. Then, for example, when a positive pressure of a predetermined value or more is applied to the inflow passage 1414, the valve member 145 deforms toward the outflow passage 1418 according to the magnitude of the positive pressure, thereby opening the valve hole 1416 (see FIG. 8F). In this way, the gas supplied from the outside of the container body 10 passes through the valve hole 1416 and is supplied to the inside of the container body 10.

When a negative pressure of the predetermined value or more is applied to the outflow passage 1418, the valve body 140 performs the same valve opening operation as when a positive pressure of the predetermined value or more is applied to the inflow passage 1414, because this is relatively the same as when the positive pressure is applied to the inflow passage.

On the contrary, when the positive pressure is applied to the outflow passage 1418, the valve member 145 is further pressed against the valve seat 1417 while remaining in close contact with the valve seat 1417, so that the gas does not pass through the valve hole 1416, and the blocking of the flow is maintained.

In the valve body 140, the predetermined value of the pressure at which the gas can flow can be adjusted by changing the material, hardness, shape, dimension, and thickness of the valve member 145 and the opening area (width and length) of the valve hole 1416.

Next, the valve body 150 for exhaust will be described. Since the valve body 150 for exhaust is basically constituted by the same components as the valve body 140 for air supply, except for the block member 141 of the valve body 140, the description of individual components will be omitted as appropriate.

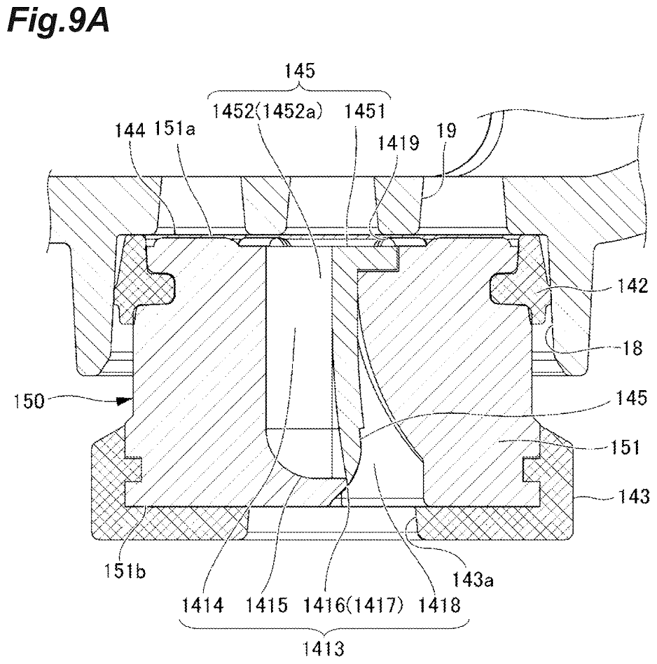

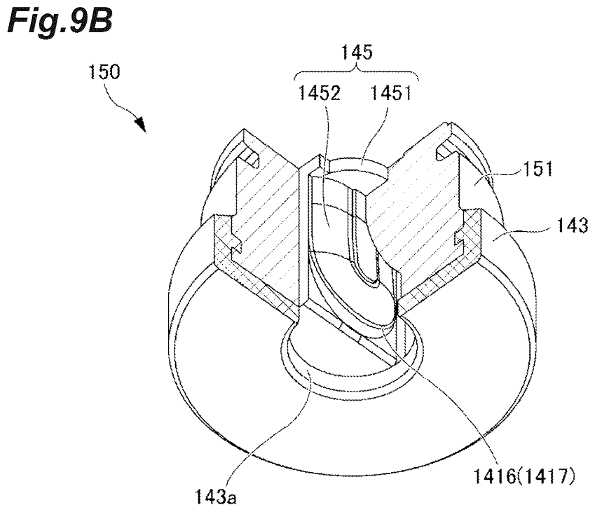

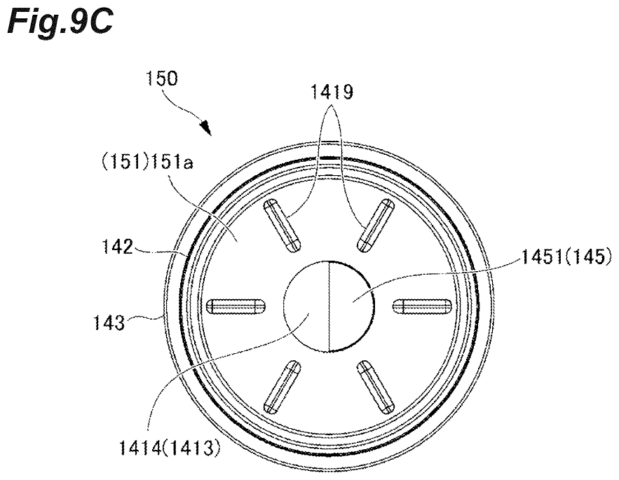

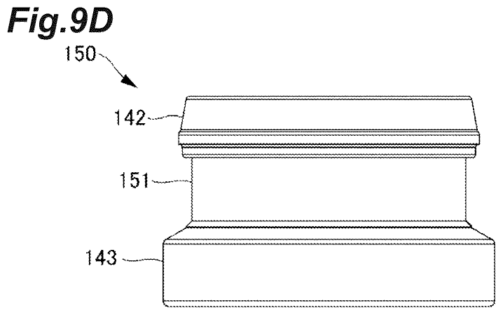

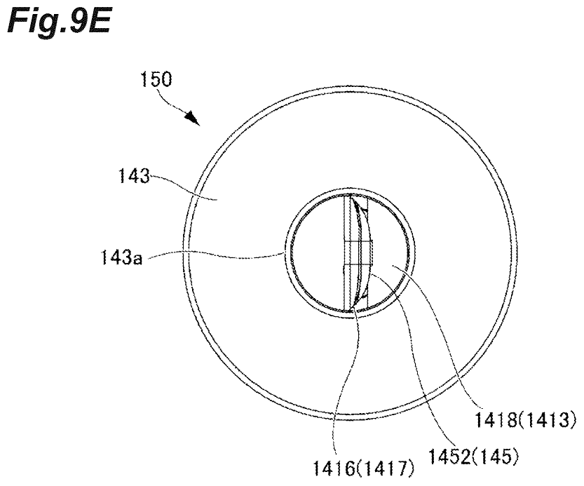

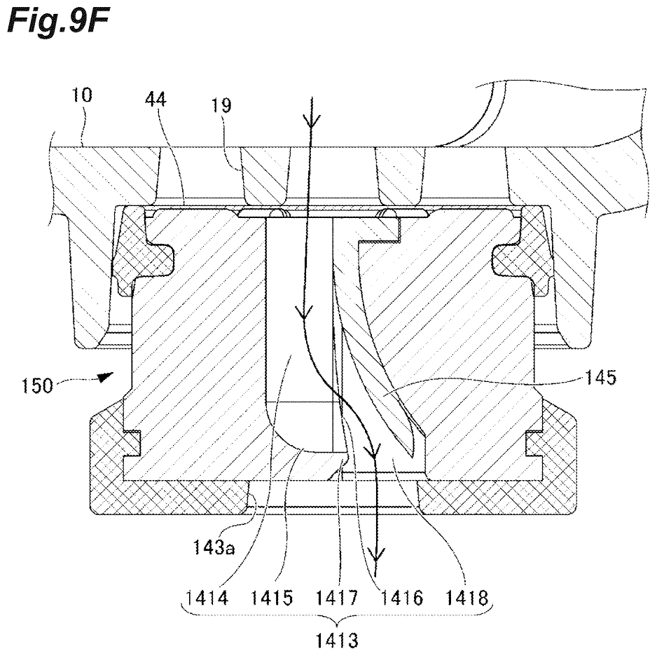

FIGS. 9A to 9F show the valve body 150 for exhaust, where FIG. 9A is a cross-sectional view, FIG. 9B is a cross-sectional perspective view, FIG. 9C is a top view, FIG. 9D is a front view, FIG. 9E is a bottom view, and FIG. 9F is a cross-sectional view showing the valve open state. A part of the container body 10 to which the valve body 150 is attached is also shown in FIG. 9A.

As shown in FIG. 9A, the valve body 150 controls the flow of gas from the container body 10, and communicates with the exhaust portion 17 through a gas flow passage (not shown) when attached to the container body 10. Contrary to the valve body 140, the valve body 150 is used for the exhaust portion 17, which enables the exhaust of gas from the container body 10 to the outside but disables the supply of gas to the inside of the container body 10.

The valve body 150 is basically obtained by inverting the structure of the valve body 140 (the valve member 145 and the communication passage 1413 of the block member 141) upside down (symmetrically). That is, the inflow passage 1414 is opened on the upper surface 151a of the block member 51, the outflow passage 1418 is opened on the lower surface 151b, and the valve hole 1416 is provided between them.

The operation of the valve body 150 for exhaust in controlling the flow of the gas is basically the reverse of that of the valve body 140 for air supply, therefore, a description thereof will be omitted. The pressure at which the valve body 150 is opened may be different from the pressure at which the valve body 140 is opened.

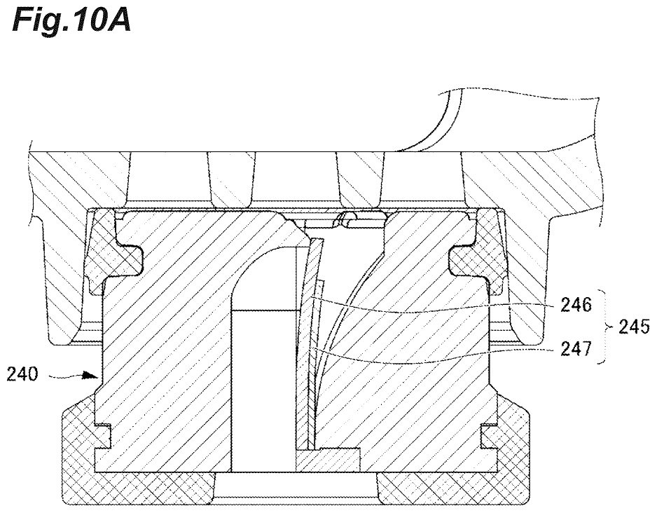

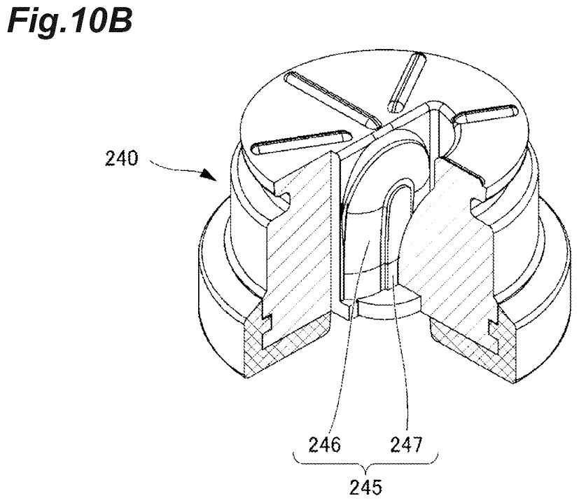

Here, a valve member 245 according to a third embodiment will be described. FIGS. 10A and 10B show a valve body 240 including the valve member 245 of the third embodiment, where FIG. 10A is a cross-sectional view and FIG. 10B is a cross-sectional perspective view. Components other than the valve member 245 have the same structure as the valve body 140, and therefore the reference numerals thereof are omitted.

The valve member 245 of the third embodiment is formed of two different members: a seal member 246 including a base portion and a seal portion; and an elastic member 247 for applying a biasing force (restoring force) to the seal member (see FIG. 10A). In the valve member 45 of the first embodiment, the seal member 246 and the elastic member 247 may be formed as different members as in the third embodiment.

Similarly to the valve member 45, the seal member 246 may be made of various rubbers, thermoplastic resins, or the like. For example, the material may be selected based on performance conditions such as prioritizing the sealing (adhesion) property with the valve seat 1417, prioritizing anti-stick property to the valve seat 1417, or prioritizing washability and dryability.

On the other hand, the elastic member 247 may be formed using various types of rubber, thermoplastic resins, or the like depending on the desired magnitude of the elastic (restoring) force. Examples of these rubbers and resins include rubber such as fluororubber and ethylene propylene rubber, thermoplastic elastomers such as polyester elastomers, polyolefin elastomers, fluorine elastomers, and urethane elastomers, and resins such as polyether ether ketone, polybutylene terephthalate, and polycarbonate. Note that the thickness can be reduced by selecting a resin material for the elastic member 247.

The elastic member 247 may use a metal leaf spring as a core material. In this case, it is desirable that the metal portion is completely covered with a rubber or resin material so that no part of the metal portion is not exposed to the outside.

The seal member 246 and the elastic member 247 may be bonded or welded to each other, or may only be in contact with each other so as to be biased. Therefore, the valve member 245 has substantially the same shape and dimensions as the valve member 45 as a whole.

Finally, a valve body 340 including the inflow passage 1414 according to a fourth embodiment will be described.

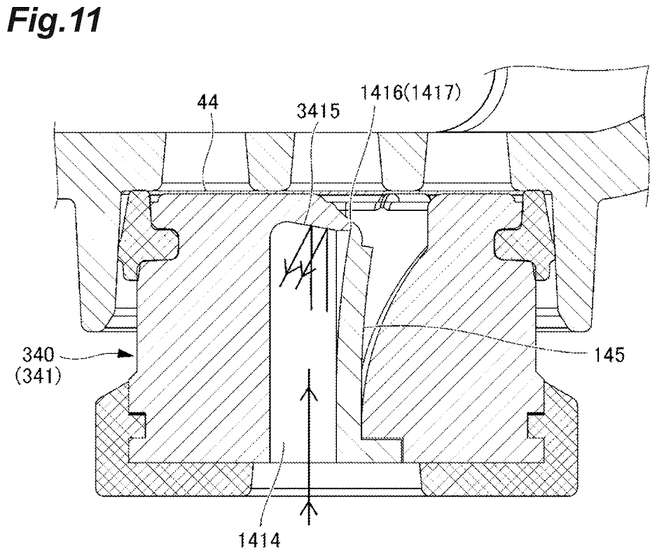

FIG. 11 is a cross-sectional view showing the valve body 340 including the inflow passage 1414 according to the fourth embodiment.

Usually, when the substrate container 1 is used, a gas is supplied from the inflow passage 244 of the valve body 140, but when the substrate container 1 is washed, a washing liquid may also be supplied. If the washing liquid remains in the inside of the valve 40 or the like after washing, the washing liquid may be brought into the inside of the substrate container 1 when the gas is supplied, and may adhere to the substrate.

Therefore, the valve body 340 of the fourth embodiment has a structure that makes it difficult for the washing liquid to enter the inside even if the washing liquid infiltrates. Specifically, the inflow passage 1414 includes an end wall 3415 inclined so as not to guide the vertically flowing fluid toward the valve hole 1416 when the vertically flowing fluid impinges thereon (see FIG. 11).

The end wall 3415 is an inclined surface that intersects the seal line between the valve member 145 and the valve seat 1417 at an angle of 90 degrees or more, preferably 100 degrees or more, on the distal end side with respect to the seal line (an imaginary line connecting the distal end and the proximal end by a straight line, since the seal region is actually curved when viewed from the cross-sectional direction).

The inflow passage 1414 is formed to extend vertically in the upstream of the valve hole 1416 similarly to the valve body 140 for air supply.

In such a valve body 340, when the washing liquid enters the inflow passage 1414 formed along the vertical direction, the washing liquid collides with the end wall 3415 and is then reflected in a direction away from the valve hole 1416 and the valve member 145. Therefore, the washing liquid is less likely to be guided toward the valve member 145. In the valve body 340 of the fourth embodiment, the eave 463 of the valve body 40 of the first embodiment may be added to the downstream of the valve hole 1416.

As explained above, the substrate container 1 of each embodiment according to the present invention is the substrate container 1 including: the container body 10 that stores a substrate; the lid 20 that closes the opening 11 of the container body 10; and the valve bodies 40 and 50 (140 and 150) that control a flow of a gas to or from the container body 10, wherein each of the valve bodies 40 and 50 include: the block member 41 (141) in which the communication passage (1413) communicating the outside and the inside of the container body 10 through the valve hole 466 (1416) is formed; and the elastically deformable plate-shaped valve member 45 that opens and closes the valve hole 466 (1416), and wherein the valve seat 467 (1417) around the valve hole 466 (1416) and the seal surface 452a (1452a) of the valve member 45 (145) are in contact with each other while being curved toward the downstream in the gas flow direction.

As a result, for example, when the gas is introduced from one (the inflow passage 1414) of the valve bodies 40 and 50 (140 and 150) and the pressure becomes positive, reaching a predetermined pressure value, the valve member 45 is elastically deformed and separated from the valve seat 467 (1417). Consequently, the introduced gas is supplied to the other side (the outflow passage 1418) of the valve bodies 40 and 50 (140 and 150). In particular, the contact region between the valve member 45 (145) and the valve seat 467 (1417) when the valve is closed is curved in a cross-sectional view, and the distal end of the valve member 45 (145) is most deformed. This results in a larger elastic restoring force at the distal end, ensuring that the adhesion force of the valve member 45 (145) to the valve seat 467 (1417) does not exhibit a significant difference between the distal end and the base 451 (1451).

Since the substrate container 1 includes the valve bodies 40 and 50 (140 and 150) which do not use metallic members, even if there are metallic corrosive residual substances on the substrate to be stored, the problem of metal corrosion does not occur, making it less likely for the valve bodies 40 and 50 (140 and 150) to fail to operate.

In addition, the humidity storage test was carried out using the substrate container 1 of the embodiment, and no significant difference was observed in the decrease in humidity with the passage of time as compared with the conventional one.

The valve member 45 (145) of the embodiment includes the planar seal surface 452a (1452a) extending in one direction (for example, the vertical direction) in a state where no external force is applied, and the valve member 45 (145) is in contact with the valve hole 466 (1416) so as to close the valve hole 466 (1416) in a state where the valve member 45 (145) is curved and elastically deformed toward the downstream in the gas flow direction. Thus, the valve member 45 (145) is brought into close contact with the valve seat 467 (1417) up to the distal end of the seal portion 452 (1452) with a uniform elastic force (elastic restoring force), so that the opening and closing of the valve hole 466 (1416) can be reliably performed.

The valve member 45 (145) of the embodiment includes the seal surface 452a which is inclined or curved from the vertical direction toward the upstream in the gas flow direction in a state where no external force is applied, and the valve member 45 is in contact with the valve hole 466 (1416) so as to close the valve hole 466 (1416) in a state where the valve member 45 is curved and elastically deformed toward the downstream in the gas flow direction. Thus, the valve member 45 (145) is brought into close contact with the valve seat 467 (1417) up to the distal end of the seal portion 452 (1452) with a uniform elastic reaction force, so that the opening and closing of the valve hole 466 (1416) can be reliably performed.

The valve member 245 of the embodiment is formed of the plate-shaped seal member 246 and the elastic member 247 for biasing the seal member 246. This makes it possible to easily design the valve member 245 having desired performances such as adhesion, anti-stick property, and elastic force, and to easily change the opening and closing pressure conditions of the valve.

The inflow passage 1414 of the embodiment includes the end wall 3415 inclined so as not to guide fluid toward the valve hole 1416 when the fluid flowing in the vertical direction collides with the end wall 3415. Thus, even if the washing liquid enters the inflow passage 1414 formed along the vertical direction, the washing liquid is reflected in the direction away from the valve hole 1416 and the valve member 145 upon colliding with the end wall 3415, thereby preventing the washing liquid from advancing the downstream of the valve hole 1416.

The valve bodies 40 and 140 of the embodiment controls the flow of the gas from the outside to the inside of the container body 10, and the valve bodies 50 and 150 of the embodiment controls the flow of the gas from the inside to the outside of the container body 10. This makes it possible to control the flow of the gas to and from the substrate container 1, respectively.

The valve bodies 40, 50, 140, and 150 of the embodiment includes the filter 44 for filtering the gas. Thus, the gas passing through the valve bodies 40, 50, 140, and 150 can be filtered. Further, by clamping the filter 44 between (the partition rib 419 of) the block members 41 and 141 and (the ventilation rib 19 of) the container body 10, the filter 44 can be prevented from falling off.

The outflow passage of the embodiment includes the eave 463 extending in a direction intersecting the vertical direction from the valve hole 466 so that the fluid passing through the valve hole 466 collides with the eave 463. Thus, even if the washing liquid passes through the valve hole 466 and enters the valve body 40, the washing liquid collides with the eave 463, preventing the washing liquid from reaching the filter 44 and entering the container body 10. Further, in the valve bodies 40 and 50, the gas for supply or exhaust can be dispersed by the eave.

The block member 41 of the embodiment includes the valve holder 46 in which the valve hole 466 is formed, and the valve cover 47 for clamping the valve member 45 between the valve holder 46 and the valve cover 47. Thus, the valve body 40 for air supply and the valve body 50 for air exhaust can share common components such as the block member 41, the valve member 45, the valve holder 46, and the valve cover 47. Additionally, by simply reversing the insertion direction of the valve assembly, which includes of the valve member 45, the valve holder 46, and the valve cover 47, into the block member 41, it is possible to select the gas flow direction from the outside to the inside or from the inside to the outside of the substrate container 1.

Although the preferred embodiments of the present invention have been described in detail above, the present invention is not limited to the above-described embodiments, and various modifications and changes can be made within the scope of the gist of the present invention described in the claims.

### Modification

In the above embodiments, the filter 44 may be disposed separately from the valve bodies 40, 50, 140, and 150 in the gas flow passage from the gas supply source to the container body 10.

In the above embodiments, the valve bodies 40, 50, 140, and 150 is configured to be attached to the through hole 18 formed in at least one of the container body 10 and the lid 20, but may be configured to be attached to a gas flow passage (pipe) provided in the container body 10 or the like, for example, in the middle of a gas flow passage communicating with at least one of the air supply portion 16 and the exhaust portion 17, as in the valve body described in Patent Document 3.

### REFERENCE SIGNS LIST

1 substrate container
10 container body, 11 opening, 12 seal surface, 13 support, 14 robotic flange, 15 manual handle, 16 air supply portion, 17 exhaust portion, 18 through hole, 19 ventilation rib
20 lid, 21 mounting groove, 22 protrusion
30 gasket
40 valve body
41 block member, 411 first cylindrical portion, 412 second cylindrical portion, 413 annular rib, 414 support shaft, 416 vent hole, 417 storage hole, 418 locking rib, 419 partition rib, 41a upper surface, 41b lower surface, 41c step portion, 41d protruding portion
43 handle
44 filter
45 valve member, 451 base portion, 452 seal portion, 452a seal surface
46 valve holder, 461 end face, 461a inflow port, 462 end face, 463 eave, 464 fitting protrusion, 465 locking recess, 466 valve hole, 467 valve seat, 466 cavity
47 valve cover, 471a outflow port, 474 valve presser, 475 locking protrusion, 46a valve seat forming surface
50 valve body
block member 51
140 valve body
141 block member, 1411 first ring groove, 1412 second ring groove, 1413 communication passage, 1414 inflow passage, 1415 end wall, 1416 valve hole, 1417 valve seat, 1418 outflow passage, 1419 partition rib, 141a upper surface, 141b lower surface, 141c step portion
142 first seal ring, 421 annular protrusion
143 second seal ring, 432 annular protrusion, 43a through hole
145 valve member, 1451 base portion, 1452 seal portion, 1452a seal surface
150 valve body
151 block member, 151a upper surface, 151b lower surface 240 valve body
245 valve member, 246 seal member, 247 elastic member 340 valve body
341 block member, 3415 end wall

1. A substrate container comprising:
a container body configured to store a substrate;
a lid configured to close an opening of the container body; and
a valve body configured to control a flow of a gas to or from the container body, wherein the valve body includes:
a block member in which a communication passage communicating an outside and an inside of the container body through a valve hole is formed; and
an elastically deformable plate-shaped valve member configured to open and close the valve hole, and
wherein a valve seat around the valve hole and a seal surface of the valve member are in contact with each other while being curved toward a downstream in a gas flow direction.

2. The substrate container according to claim 1,
wherein the seal surface extends along one direction in a state where no external force is applied, and
wherein the valve member is in contact with the valve hole so as to close the valve hole in a state where the valve member is curved and elastically deformed toward the downstream in the gas flow direction.

3. The substrate container according to claim 1,
wherein the seal surface is inclined or curved toward an upstream in the gas flow direction in a state where no external force is applied, and
wherein the valve member is in contact with the valve hole so as to close the valve hole in a state where the valve member is curved and elastically deformed toward the downstream in the gas flow direction.

4. The substrate container according to claim 3,
wherein the valve member is formed of a plate-shaped seal member and an elastic member configured to bias the seal member.

5. The substrate container according to claim 1,
wherein the communication passage includes an inflow passage extending in a vertical direction toward an upstream of the valve hole, and
wherein the inflow passage includes an end wall inclined so as not to guide fluid toward the valve hole when the fluid flowing in the vertical direction collides with the end wall.

6. The substrate container according to claim 3,
wherein the valve body controls the flow of the gas from the inside to the outside of the container body.

7. The substrate container according to claim 3,
wherein the valve body controls the flow of the gas from the outside to the inside of the container body.

8. The substrate container according to claim 3,
wherein the valve body includes a filter configured to filter the gas.

9. The substrate container according to claim 3,
wherein the communication passage includes an outflow passage extending toward a downstream of the valve hole, and
wherein the outflow passage includes an eave extending in a direction intersecting a vertical direction from the valve hole so that fluid having passed through the valve hole collides with the eave.

10. The substrate container according to claim 3,
wherein the block member includes a valve holder in which the valve hole is formed and a valve cover configured to clamp the valve member between the valve holder and the valve cover.
